(19) United States
(12) Patent Application Publication
(10) Pub. No.: US 2016/0181222 A1
(43) Pub. Date: Jun. 23, 2016

(54) PICKHEAD FOR SOLDER BALL PLACEMENT ON AN INTEGRATED CIRCUIT PACKAGE

(71) Applicants: Mohit Sood, Chandler, AZ (US); Wei Tan, Chandler, AZ (US); George F. Robinson, Chandler, AZ (US); Hin Huat Teoh, Bedong (MY); Tean Wee Ong, Bayan Lepas (MY); Ha Ong Wong, Chandler, AZ (US); Boon Yee Ee, Bayan Lepas (MY); Kok Beng Hong, Taman Kempas (MY)

(72) Inventors: Mohit Sood, Chandler, AZ (US); Wei Tan, Chandler, AZ (US); George F. Robinson, Chandler, AZ (US); Hin Huat Teoh, Bedong (MY); Tean Wee Ong, Bayan Lepas (MY); Ha Ong Wong, Chandler, AZ (US); Boon Yee Ee, Bayan Lepas (MY); Kok Beng Hong, Taman Kempas (MY)

(21) Appl. No.: 14/581,280

(22) Filed: Dec. 23, 2014

(51) Int. Cl. H01L 23/00; B23K 3/06

(52) U.S. Cl. CPC H01L 24/75; B23K 3/0623; H01L 24/14; H01L 24/11; H01L 2924/014; H01L 2224/75621; H01L 2924/37001

(57) ABSTRACT

Embodiments of the present disclosure are directed toward a pickhead for solder ball placement on an integrated circuit (IC) package, and associated systems and techniques. The pickhead may include a body having a bottom surface that defines a bottom plane of the pickhead. The pickhead may further include a plurality of cavities in the bottom surface to hold respective solder balls to be placed on the IC package. Individual cavities of the plurality of cavities may be recessed from the bottom surface by different recess amounts to provide different extensions of the solder balls with respect to the bottom plane. Other embodiments may be described and/or claimed.

### FIELD

Embodiments of the present disclosure generally relate to the field of integrated circuit (IC) assemblies, and more particularly, to pickheads for solder ball placement on IC packages and associated systems and techniques.

### BACKGROUND

Integrated circuit (IC) packages often include solder balls that are coupled to conductive pads on a substrate of the IC package. The solder balls are used to mount the IC package to a printed circuit board (PCB) and to communicatively couple the IC package to other components on the PCB (e.g., via traces). The IC package can become warped during manufacturing of the IC package, thus causing the surface of the substrate to be uneven. The uneven surface can increase the probability that one or more solder balls will not attach correctly to the associated pad during the ball attach process.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an example pickhead and integrated circuit (IC) package, in accordance with some embodiments.

FIG. 2 schematically illustrates a bottom view of an example pickhead, in accordance with some embodiments.

FIG. 3 schematically illustrates a bottom view of an example pickhead showing arrangement of regions of cavities, in accordance with some embodiments.

FIG. 4 is a flow chart that illustrates a ball attach process, in accordance with some embodiments.

FIG. 5 schematically illustrates a computing device that includes an IC package assembly as described herein, in accordance with some embodiments.

### DETAILED DESCRIPTION

Embodiments of the present disclosure describe a pickhead for solder ball placement on an integrated circuit (IC) package, and associated systems and techniques. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group), and/or memory (shared, dedicated, or group) that execute one or more software or firmware programs, a combinational logic circuit, and/or other suitable components that provide the described functionality.

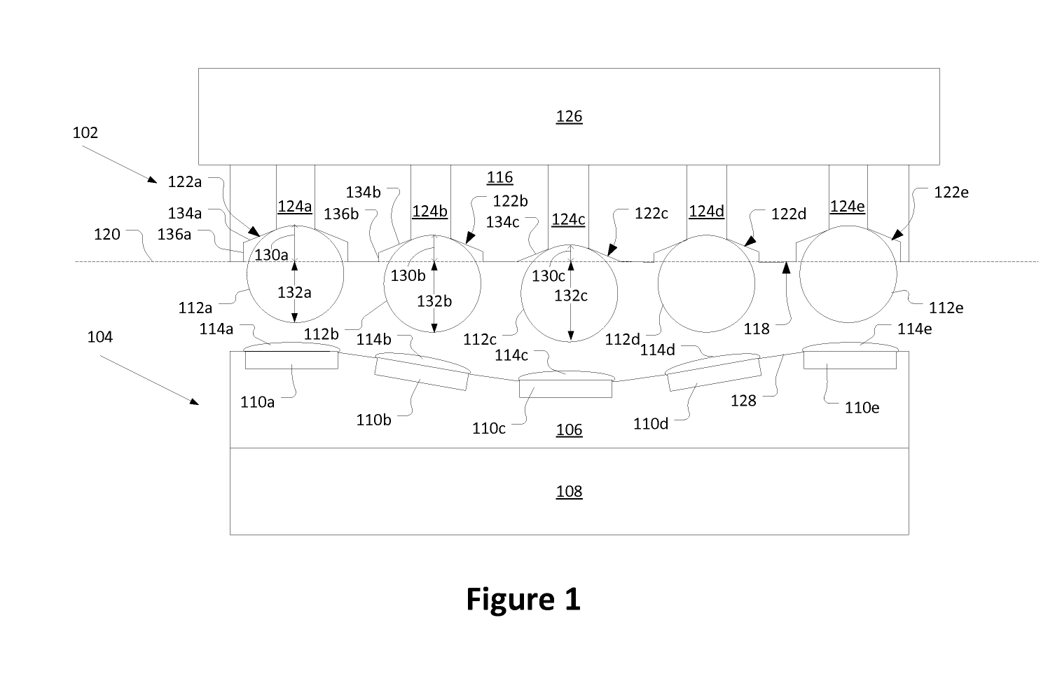

FIG. 1 schematically illustrates a cross-section side view of an example pickhead 102 in accordance with various embodiments. FIG. 1 further illustrates a cross-section side view of an integrated circuit (IC) package 104 (hereinafter “package 104”). Package 104 may include a substrate 106 and a die 108 coupled to the substrate 106. The substrate 106 may further include a plurality of conductive pads 110a-e disposed on a surface 107 of the substrate 106. The substrate 106 may include one or more routing structures (not shown) such as, for example, conductive traces, vias, and the like to route electrical signals of the die 108 to the pads 110a-e.

In various embodiments, the pickhead 102 may be used to couple a plurality of solder balls 112a-e to respective pads 110a-e of the package 104. For example, the pickhead 102 may drop the solder balls 112a-e on respective pads 110a-e, and the solder balls 112a-e may be bonded to the pads 110a-e by flux 114a-e disposed on the pads 110a-e.

In various embodiments, the pickhead 102 may include a body 116 having a bottom surface 118 that defines a bottom plane 120 of the pickhead 102. For example, the bottom surface 118 may be substantially co-planar with the bottom plane 120. The pickhead 102 may further include a plurality of cavities 122a-e in the bottom surface to hold the respective solder balls 112a-e. For example, the cavities 122a-e may include a rear opening 124a-e to receive vacuum pressure (e.g., from a vacuum 126) to hold the respective solder ball 112a-e. The body 116 of the pickhead 102 may formed of any suitable material, and the pickhead 102 may be made using any suitable manufacturing process.

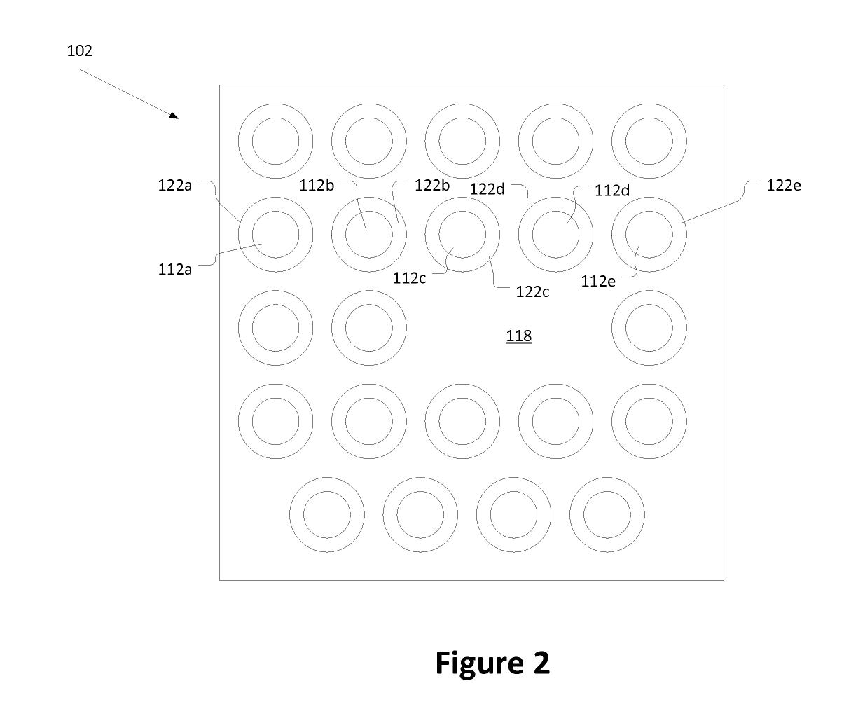

In various embodiments, the solder balls 112a-e may be part of a ball grid array, and the cavities 122a-e may be arranged in the bottom surface 118 to align with respective pads 110a-e of the package 104. For example, FIG. 2 illustrates a bottom view of the pickhead 102 in accordance with some embodiments, showing the bottom surface 118 and a plurality of cavities (including cavities 122a-e) that hold respective solder balls (including solder balls 112a-e). It will be apparent that the arrangement of the cavities in the pickhead 102 shown in FIG. 2 is merely an example, and other embodiments may include any suitable number and/or arrangement of cavities. For example, in some embodiments, the pickhead 102 may include significantly more cavities than are shown in FIGS. 1 and 2.

Referring again to FIG. 1, in various embodiments, a surface 128 of the package 104, on which the pads 110a-e are disposed, may be warped (e.g., non-planar) according to a warpage pattern. For example, as shown in FIG. 1, the surface 128 of the package 104 may be relatively higher toward the edges of the surface 128 and may be relatively lower in the middle portion of the surface. In other embodiments, the surface 128 may exhibit a different warpage pattern. The warpage pattern of the surface 128 may be substantially consistent across packages 104 of the same design.

In various embodiments, the individual cavities 122a-e of the pickhead 102 may be recessed from the bottom surface 118 by different amounts to provide different extensions of the solder balls 112a-e from the pickhead 102 with respect to the bottom plane 120. The recess amount of the individual cavities 122a-e may refer to a distance that the respective solder ball 122a-e is recessed into the pickhead 102 with respect to the bottom plane 120 (e.g., above the bottom plane 120 as shown in FIG. 1). The extension of the solder ball 122a-e may refer to a distance that the respective solder ball 122a-e protrudes out of the pickhead with respect to the bottom plane 120 (e.g., below the bottom plane 120 as shown in FIG. 1). In various embodiments, the recess amounts of the cavities 122a-e may correspond to a warpage pattern of the package 104.

For example, as shown in FIG. 1, cavities 122a and 122e may be recessed by a first recess amount 130a to provide a first extension 132a for the respective solder balls 112a and 112e. The cavities 122b and 122d may be recessed by a second recess amount 130b to provide a second extension 132b for the respective solder balls 112b and 112d. The second recess amount 130b may be less than the first recess amount 130a, and the second extension 132b may be greater than the first extension 132a. Accordingly, solder balls 112b and 112d may extend further below the bottom plane 120 than the solder balls 112a and 112e.

In some embodiments, the cavity 122c may be recessed by a third recess amount 130c to provide a third extension 132c for the solder ball 112c. The third recess amount 130c may be less than the first recess amount 130a and the second recess amount 130b, and the third extension 132c may be greater than the first extension 132a and second extension 132b. Accordingly, solder ball 112c may extend further below the bottom plane 120 than the solder balls 112a, 112b, 112d, and 112e.

In one non-limiting example, the solder balls 122a-e may have a diameter of about 16 mil (16 millionths of an inch, e.g., about 400 micrometers (μm)), the first extension 132a may be about 220 μm (e.g., about 55% of the diameter of the solder balls 122a-e), the second extension 132b may be about 270 μm (e.g., about 67.5% or about two-thirds of the diameter of the solder balls 122a-e), and the third extension 132c may be about 320 μm (e.g., about 80% of the diameter of the solder balls 122a-e). It will be apparent that other values for the extensions 132a-c and/or relationships between the extensions 132a-c may be used in other embodiments.

In various embodiments, the different recess amounts of the cavities 122a-e, corresponding to the warpage pattern of the surface 107, may decrease the ball drop distance for solder balls (e.g., solder balls 112b-d) to be dropped on pads (e.g., pads 110b-d) in lower areas of the surface 107. The decreased ball drop distance may provide a higher likelihood that the solder balls 112a-e will be successfully bonded to the respective pads 110a-e in a desired configuration (e.g., without missing the pad 110a-e or being significantly off-center of the pad 110a-e). Accordingly, the pickhead 102 may provide increased yield of packages 104 during the ball attach process.

For example, it may be desirable for the ball drop distance to be less than 40% of the diameter of the solder balls 112a-e for consistently accurate placement of the solder balls 112a-e on the package 104. The pickhead 102 described herein may provide a ball drop distance of less than 40% of the diameter of the solder balls 112a-e for substantially all solder balls 112a-e of the ball grid array.

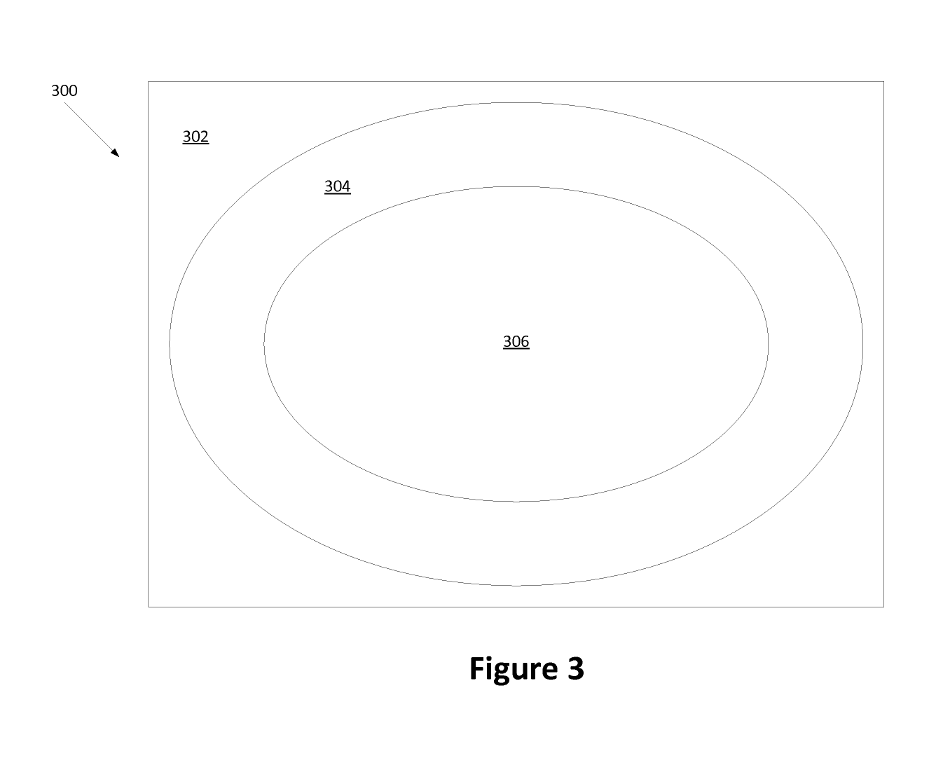

In some embodiments, the pickhead 102 may be divided into a plurality of regions, and the cavities included in an individual region may have a same recess amount. For example, FIG. 3 illustrates a pickhead 300 in accordance with various embodiments. Pickhead 300 may include a first region 302, a second region 304, and a third region 306 that each include one or more cavities. The cavities in the first region 302 may be included in a first set of cavities, the cavities in the second region 304 may be included in a second set of cavities, and the cavities in the third region may be included in a third set of cavities. In some embodiments, the cavities in the second set of cavities may have a lesser recess amount than the cavities in the first set of cavities, and the cavities of third set of cavities may have a lesser recess amount than the cavities in the first and second sets of cavities.

As shown in FIG. 3, the first region 302 may generally correspond to an outer region of the pickhead 300 (e.g., including the corner regions), the third region 306 may correspond to a middle region of the pickhead 300, and the second region 304 may correspond to an intermediate region of the pickhead 300. It will be apparent that other numbers and/or configurations for the regions 302, 304, and/or 306 may be used in other embodiments.

Referring again to FIG. 1, cavities 122a-c may include a rear annular surface 134a-c disposed around the rear opening 124a-c. The rear annular surface 134a-c may be disposed at an angle with respect to the bottom plane 120. A depth of the rear annular surface 134a-c with respect to the bottom plane 120 may be based on the recess amount 130a-c of the respective cavity 122a-c. For example, the annular surface 134b may be deeper in the pickhead 102 (e.g., further from the bottom plane 120) than the annular surface 134c, and the annular surface 134a may be deeper in the pickhead 102 than both the annular surface 134b and the annular surface 134c.

The cavities 122a, 122b may further include a side wall 136a-b coupled between the rear annular surface 134a-b and the bottom surface 118. The side wall 136a-b may be substantially perpendicular to the bottom plane 120 (e.g., perpendicular to the bottom surface 118). A height of the side wall 136a-b may be based on the recess amount 130a-b of the respective cavity 122a-b. For example, the height of side wall 136a may be greater than the height of side wall 136b. In various embodiments, the vertical side walls 136a-b may help direct the solder balls 112a-b toward the respective pads 110a-b upon release of the solder balls 112a-b from the pickhead 102.

In some embodiments, the cavity 122c may not include a side wall. For example, the rear annular surface 134c may connect to the bottom surface 118. In other embodiments, the cavity 122c may include a side wall with a height that is less than the height of the cavities 122a and 122b.

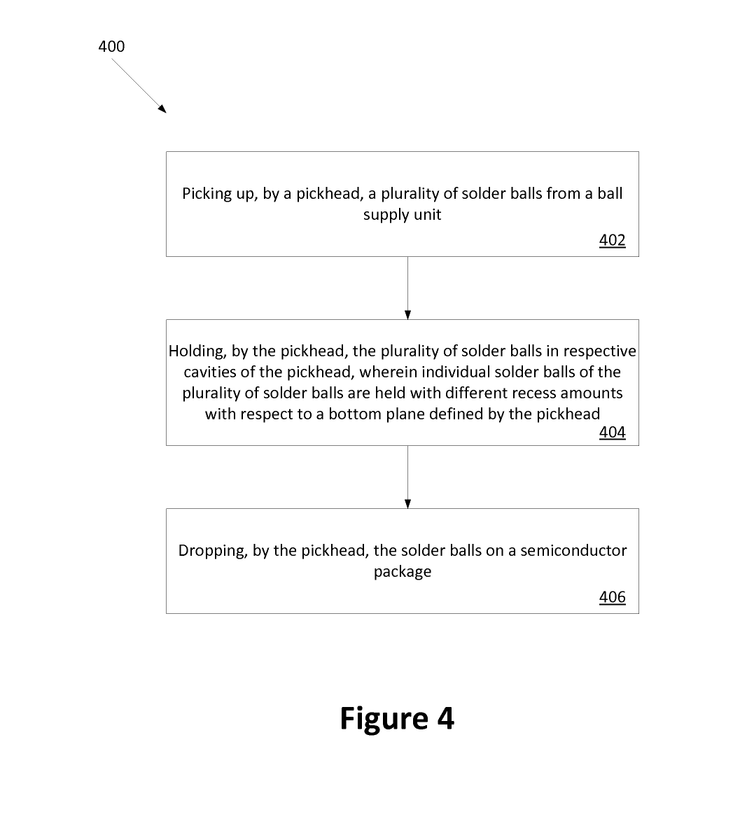

FIG. 4 is a flow chart illustrating a ball attach process 400 in accordance with various embodiments. Ball attach proess 400 may be used to attach solder balls (e.g., solder balls 112a-e to respective pads (e.g., pads 110a-e) of an IC package (e.g., package 104). One or more aspects of ball attach process 400 may be performed by a pickhead (e.g., pickhead 102).

At block 402, the ball attach process 400 may include picking up, by the pickhead, a plurality of solder balls from a ball supply unit. The ball supply unit may hold the solder balls in an arrangement corresponding to the cavities of the pickhead (e.g., corresponding to the desired arrangement of the solder balls on the IC package). The pickhead may pick up the solder balls from the ball supply unit using vacuum pressure applied through a rear opening of the cavities.

At block 404, the ball attach process 400 may include holding, by the pickhead, the plurality of solder balls in respective cavities of the pickhead. Individual solder balls of the plurality of solder balls may be held with different recess amounts with respect to a bottom plane defined by the pickhead, as described herein. The recess amounts with which the solder balls are held by the pickhead may correspond to a warpage pattern of the IC package.

The solder balls may be held by the pickhead using vacuum pressure applied through the rear opening of the cavities. In some embodiments, the pickhead may pick up the solder balls at block 402 using a first vacuum pressure, and then may hold the solder balls at block 404 using a second vacuum pressure that is less than the first vacuum pressure.

At block 406, the ball attach process 400 may include dropping, by the pickhead, the solder balls on the IC package. For example, the pickhead may drop the solder balls on respective pads of the IC package. The solder balls may be bonded and communicatively coupled to the pads by flux disposed on the pads.

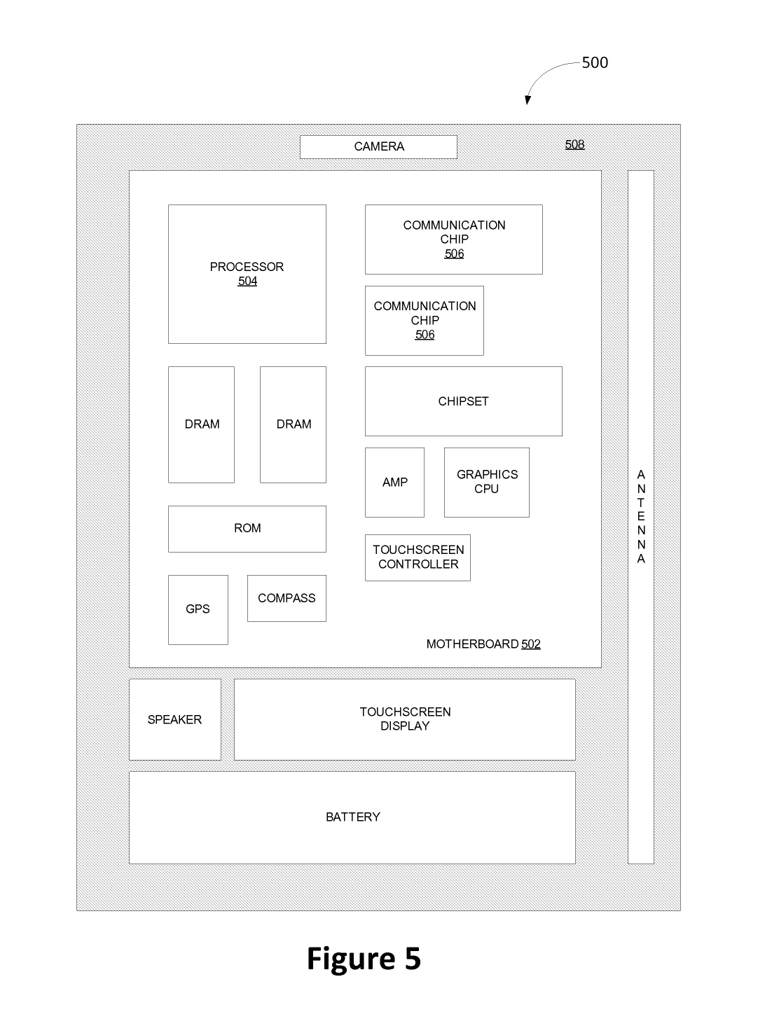

Embodiments of the present disclosure may be implemented into a system using any suitable hardware and/or software to configure as desired. Additionally, the IC package described herein (e.g., package 104) may be included in any suitable computing device. For example, FIG. 5 schematically illustrates a computing device 500 that includes an IC package as described herein, in accordance with some embodiments. The computing device 500 may house a board such as motherboard 502 (e.g., in housing 508). The motherboard 502 may include a number of components, including but not limited to a processor 504 and at least one communication chip 506. The processor 504 may be physically and electrically coupled to the motherboard 502. In some implementations, the at least one communication chip 506 may also be physically and electrically coupled to the motherboard 502. In further implementations, the communication chip 506 may be part of the processor 504.

Depending on its applications, computing device 500 may include other components that may or may not be physically and electrically coupled to the motherboard 502. These other components may include, but are not limited to, volatile memory (e.g., dynamic random access memory (DRAM)), non-volatile memory (e.g., read only memory (ROM)), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 506 may enable wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 706 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 706 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 506 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 506 may operate in accordance with other wireless protocols in other embodiments.

The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, EV-DO, and others.

In various embodiments, the processor 504 of the computing device 500 may be packaged in an IC package assembly (e.g., IC package 104 of FIG. 1) as described herein. The processor 504 may include solder balls bonded to pads of the processor 504 to communicatively couple the processor 504 to the motherboard 502. The term “processor” may refer to any device or portion of a device that processes electronic data from registers and/or memory to transform that electronic data into other electronic data that may be stored in registers and/or memory.

Additionally, or alternatively, the communication chip 506 may include a die that may be packaged in an IC package assembly (e.g., IC package 104 of FIG. 1) as described herein. In further implementations, another component (e.g., memory device or other integrated circuit device) housed within the computing device 500 may include a die that may be packaged in an IC package assembly (e.g., IC package 104 of FIG. 1) as described herein.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. The computing device 500 may be a mobile computing device in some embodiments. In further implementations, the computing device 500 may be any other electronic device that processes data.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

Some non-limiting Examples of various embodiments are presented below.

Example 1 is a pickhead, comprising: a body having a bottom surface that defines a bottom plane of the pickhead; and a plurality of cavities in the bottom surface to hold respective solder balls to be placed on an integrated circuit (IC) package, wherein individual cavities of the plurality of cavities are recessed from the bottom surface by different recess amounts to provide different extensions of the solder balls with respect to the bottom plane.

Example 2 is the pickhead of Example 1, wherein the recess amounts correspond to a warpage pattern of the IC package.

Example 3 is the pickhead of Example 1, wherein the plurality of cavities include a first set of cavities including a plurality of cavities that are recessed by a first recess amount and a second set of cavities including a plurality of cavities that are recessed by a second recess amount, wherein the second recess amount is less than the first recess amount.

Example 4 is the pickhead of Example 3, wherein the plurality of cavities further include a third set of cavities including a plurality of cavities that are recessed by a third recess amount.

Example 5 is the pickhead of Example 3, wherein the first set of cavities includes a plurality of cavities in an outer region of the pickhead, and wherein the second set of cavities includes a plurality of cavities in a middle region of the pickhead.

Example 6 is the pickhead of any one of Examples 1 to 5, wherein the individual cavities of the plurality of cavities include a rear opening to receive vacuum pressure to hold the respective solder ball.

Example 7 is the pickhead of Example 6, wherein the individual cavities further include a rear annular surface disposed around the rear opening, wherein the rear annular surface is disposed at an angle with respect to the bottom plane, and wherein a depth of the rear annular surface with respect to the bottom plane is based on the recess amount of the cavity.

Example 8 is the pickhead of Example 7, wherein the individual cavities further include a side wall coupled between the rear annular surface of the cavity and the bottom surface of the pickhead, wherein the side wall is substantially perpendicular to the bottom plane, and wherein a height of the side wall is based on the recess amount of the cavity.

Example 9 is a method comprising: picking up, by a pickhead, a plurality of solder balls from a ball supply unit; holding, by the pickhead, the plurality of solder balls in respective cavities of the pickhead, wherein individual solder balls of the plurality of solder balls are held with different recess amounts with respect to a bottom plane defined by the pickhead; and dropping, by the pickhead, the solder balls on an integrated circuit (IC) package.

Example 10 is the method of Example 9, wherein the recess amounts with which the solder balls are held correspond to a warpage pattern of the IC package.

Example 11 is the method of Example 9 or Example 10, wherein the holding the plurality of solder balls includes holding a first set of solder balls with a first recess amount and holding a second set of solder balls with a second recess amount, wherein the second recess amount is less than the first recess amount.

Example 12 is the method of Example 11, further comprising holding a third set of solder balls with a third recess amount.

Example 13 is the method of Example 11, wherein the dropping includes dropping the first set of solder balls in an outer region of the IC package and dropping the second set of solder balls in a middle region of the IC package.

Example 14 is the method of Example 9, wherein the holding includes holding the solder balls using vacuum pressure.

Example 15 is a system comprising an integrated circuit (IC) package and a pickhead. The IC package includes a substrate and a plurality of pads formed on the substrate. The pickhead includes: a body having a bottom surface that defines a bottom plane of the pickhead; and a plurality of cavities in the bottom surface to hold respective solder balls to be placed on respective pads of the IC package, wherein individual cavities of the plurality of cavities are recessed from the pickhead by different recess amounts to provide different extensions of the solder balls with respect to the bottom plane.

Example 16 is the system of Example 15, wherein the recess amounts the cavities correspond to a warpage pattern of the IC package.

Example 17 is the system of Example 15, wherein the plurality of cavities include a first set of cavities including a plurality of cavities that are recessed by a first recess amount and a second set of cavities including a plurality of cavities that are recessed by a second recess amount, wherein the second recess amount is less than the first recess amount.

Example 18 is the system of Example 17, wherein the plurality of cavities further include a third set of cavities including a plurality of cavities that are recessed by a third recess amount.

Example 19 is the system of Example 17, wherein the first set of cavities includes a plurality of cavities in an outer region of the pickhead, and wherein the second set of cavities includes a plurality of cavities in a middle region of the pickhead.

Example 20 is the system of any one of Examples 15 to 19, wherein the individual cavities of the plurality of cavities include a rear opening to receive vacuum pressure to hold the respective solder ball.

Example 21 is the system of Example 20, wherein the individual cavities further include a rear annular surface disposed around the rear opening, wherein the rear annular surface is disposed at an angle with respect to the bottom plane, and wherein a depth of the rear annular surface with respect to the bottom plane is based on the recess amount of the cavity.

Example 22 is the system of Example 21, wherein the individual cavities further include a side wall coupled between the rear annular surface of the cavity and the bottom surface of the pickhead, wherein the side wall is substantially perpendicular to the bottom plane, and wherein a height of the side wall is based on the recess amount of the cavity.

Example 23 is the system of Example 15, further comprising a flux disposed on the pads to bond the solder balls to the pads.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A pickhead, comprising:
a body having a bottom surface that defines a bottom plane of the pickhead; and
a plurality of cavities in the bottom surface to hold respective solder balls to be placed on an integrated circuit (IC) package, wherein individual cavities of the plurality of cavities are recessed from the bottom surface by different recess amounts to provide different extensions of the solder balls with respect to the bottom plane.

2. The pickhead of claim 1, wherein the recess amounts correspond to a warpage pattern of the IC package.

3. The pickhead of claim 1, wherein the plurality of cavities include a first set of cavities including a plurality of cavities that are recessed by a first recess amount and a second set of cavities including a plurality of cavities that are recessed by a second recess amount, wherein the second recess amount is less than the first recess amount.

4. The pickhead of claim 3, wherein the plurality of cavities further include a third set of cavities including a plurality of cavities that are recessed by a third recess amount.

5. The pickhead of claim 3, wherein the first set of cavities includes a plurality of cavities in an outer region of the pickhead, and wherein the second set of cavities includes a plurality of cavities in a middle region of the pickhead.

6. The pickhead of claim 1, wherein the individual cavities of the plurality of cavities include a rear opening to receive vacuum pressure to hold the respective solder ball.

7. The pickhead of claim 6, wherein the individual cavities further include a rear annular surface disposed around the rear opening, wherein the rear annular surface is disposed at an angle with respect to the bottom plane, and wherein a depth of the rear annular surface with respect to the bottom plane is based on the recess amount of the cavity.

8. The pickhead of claim 7, wherein the individual cavities further include a side wall coupled between the rear annular surface of the cavity and the bottom surface of the pickhead, wherein the side wall is substantially perpendicular to the bottom plane, and wherein a height of the side wall is based on the recess amount of the cavity.

9. A method comprising:
picking up, by a pickhead, a plurality of solder balls from a ball supply unit;
holding, by the pickhead, the plurality of solder balls in respective cavities of the pickhead, wherein individual solder balls of the plurality of solder balls are held with different recess amounts with respect to a bottom plane defined by the pickhead; and
dropping, by the pickhead, the solder balls on an integrated circuit (IC) package.

10. The method of claim 9, wherein the recess amounts with which the solder balls are held correspond to a warpage pattern of the IC package.

11. The method of claim 9, wherein the holding the plurality of solder balls includes holding a first set of solder balls with a first recess amount and holding a second set of solder balls with a second recess amount, wherein the second recess amount is less than the first recess amount.

12. The method of claim 11, further comprising holding a third set of solder balls with a third recess amount.

13. The method of claim 11, wherein the dropping includes dropping the first set of solder balls in an outer region of the IC package and dropping the second set of solder balls in a middle region of the IC package.

14. The method of claim 9, wherein the holding includes holding the solder balls using vacuum pressure.

15. A system comprising:
an integrated circuit (IC) package including a substrate and a plurality of pads formed on the substrate;
a pickhead including:
a body having a bottom surface that defines a bottom plane of the pickhead; and
a plurality of cavities in the bottom surface to hold respective solder balls to be placed on respective pads of the IC package, wherein individual cavities of the plurality of cavities are recessed from the pickhead by different recess amounts to provide different extensions of the solder balls with respect to the bottom plane.

16. The system of claim 15, wherein the recess amounts the cavities correspond to a warpage pattern of the IC package.

17. The system of claim 15, wherein the plurality of cavities include a first set of cavities including a plurality of cavities that are recessed by a first recess amount and a second set of cavities including a plurality of cavities that are recessed by a second recess amount, wherein the second recess amount is less than the first recess amount.

18. The system of claim 17, wherein the plurality of cavities further include a third set of cavities including a plurality of cavities that are recessed by a third recess amount.

19. The system of claim 17, wherein the first set of cavities includes a plurality of cavities in an outer region of the pickhead, and wherein the second set of cavities includes a plurality of cavities in a middle region of the pickhead.

20. The system of claim 15, wherein the individual cavities of the plurality of cavities include a rear opening to receive vacuum pressure to hold the respective solder ball.

21. The system of claim 20, wherein the individual cavities further include a rear annular surface disposed around the rear opening, wherein the rear annular surface is disposed at an angle with respect to the bottom plane, and wherein a depth of the rear annular surface with respect to the bottom plane is based on the recess amount of the cavity.

22. The system of claim 21, wherein the individual cavities further include a side wall coupled between the rear annular surface of the cavity and the bottom surface of the pickhead, wherein the side wall is substantially perpendicular to the bottom plane, and wherein a height of the side wall is based on the recess amount of the cavity.

23. The system of claim 15, further comprising a flux disposed on the pads to bond the solder balls to the pads.
